(19) United States
(12) Patent Application Publication
(10) Pub. No.: US 2006/0002442 A1
(43) Pub. Date: Jan. 5, 2006

(54) Light emitting devices having current blocking structures and methods of fabricating light emitting devices having current blocking structures

(76) Inventors: Kevin Haberern, Cary, NC (US); Michael John Bergmann, Chapel Hill, NC (US); Van Mieczkowski, Apex, NC (US); David Todd Emerson, Chapel Hill, NC (US)

Correspondence Address: MYERS BIGEL SIBLEY & SAJOVEC, PO BOX 37428, RALEIGH, NC, 27627, US

(21) Appl. No.: 10/881,814

(22) Filed: Jun. 30, 2004

(51) Int. Cl. H01S 5/00

(52) U.S. Cl. 372/46.01; 372/44.01

(57) ABSTRACT

Light emitting devices and methods of fabricating light emitting devices having a current blocking mechanism below the wire bond pad are provided. The current blocking mechanism may be a reduced conduction region in an active region of the device. The current blocking mechanism could be a damage region of a layer on which a contact is formed. The current blocking mechanism could be a Schottky contact between an ohmic contact and the active region of the device. A semiconductor junction, such as a PN junction could also be provided between the ohmic contact and the active region.

### FIELD OF THE INVENTION

This invention relates to semiconductor light emitting devices and fabricating methods therefor.

### BACKGROUND OF THE INVENTION

Semiconductor light emitting devices, such as Light Emitting Diodes (LEDs) or laser diodes, are widely used for many applications. As is well known to those having skill in the art, a semiconductor light emitting device includes a semiconductor light emitting element having one or more semiconductor layers that are configured to emit coherent and/or incoherent light upon energization thereof. As is well known to those having skill in the art, a light emitting diode or laser diode, generally includes a diode region on a microelectronic substrate. The microelectronic substrate may be, for example, gallium arsenide, gallium phosphide, alloys thereof, silicon carbide and/or sapphire. Continued developments in LEDs have resulted in highly efficient and mechanically robust light sources that can cover the visible spectrum and beyond. These attributes, coupled with the potentially long service life of solid state devices, may enable a variety of new display applications, and may place LEDs in a position to compete with the well entrenched incandescent and fluorescent lamps.

Much development interest and commercial activity recently has focused on LEDs that are fabricated in or on silicon carbide, because these LEDs can emit radiation in the blue/green portions of the visible spectrum. See, for example, U.S. Pat. No. 5,416,342 to Edmond et al., entitled Blue Light-Emitting Diode With High External Quantum Efficiency, assigned to the assignee of the present application, the disclosure of which is hereby incorporated herein by reference in its entirety as if set forth fully herein. There also has been much interest in LEDs that include gallium nitride-based diode regions on silicon carbide substrates, because these devices also may emit light with high efficiency. See, for example, U.S. Pat. No. 6,177,688 to Linthicum et al., entitled Pendeoepitaxial Gallium Nitride Semiconductor Layers On Silicon Carbide Substrates, the disclosure of which is hereby incorporated herein by reference in its entirety as if set forth fully herein.

The efficiency of conventional LEDs may be limited by their inability to emit all of the light that is generated by their active region. When an LED is energized, light emitting from its active region (in all directions) may be prevented from exiting the LED by, for example, a light absorbing wire bond pad. Typically, in gallium nitride based LEDs, a current spreading contact layer is provided to improve the uniformity of carrier injection across the cross section of the light emitting device. Current is injected into the p-side of the LED through the bond pad and the p-type contact. Light generated in an active region of the device is proportional to the carrier injection. Thus, a substantially uniform photon emission-across the active region may result from the use of a current spreading layer, such as a substantially transparent p-type contact layer. However, a wire bond pad is typically not a transparent structure and, therefore, photons emitted from the active region of the LED that are incident upon the wire bond pad may be absorbed by the wire bond pad. For example, in some instances approximately 70% of the light incident on the wire bond pad may be absorbed. Such photon absorption may reduce the amount of light that escapes from the LED and may decrease the efficiency of the LED.

### SUMMARY OF THE INVENTION

Some embodiments of the present invention provide light emitting devices and/or methods of fabricating light emitting devices including an active region of semiconductor material and a first contact on the active region. The first contact has a bond pad region thereon. A reduced conduction region is disposed in the active region beneath the bond pad region of the first contact and configured to block current flow through the active region in the region beneath the bond pad region of the first contact. A second contact is electrically coupled to the active region.

In further embodiments of the present invention, the reduced conduction region extends through the active region. The reduced conduction region may extend from the first contact to the active region, into the active region or through the active region. Also, a p-type semiconductor material may be disposed between the first contact and the active region. In such a case, the reduced conduction region may extend from the first contact, through the p-type semiconductor material and through the active region.

In additional embodiments of the present invention, the active region includes a Group III-nitride based active region. A bond pad may also be provided on the first contact in the bond pad region. The reduced conduction region may be self-aligned with the bond pad. The reduced conduction region may be an insulating region. The reduced conduction region may also be a region that is not light absorbing. The reduced conduction regions may include an implanted region.

In still other embodiments of the present invention, light emitting devices and methods of fabricating light emitting devices are provided that include a Group III-nitride based active region and a first contact directly on a Group II-nitride based layer on the active region. The first contact has a first portion that makes ohmic contact to the Group III-nitride based layer and a second portion that does not make ohmic contact to the Group III-nitride based layer. The second portion corresponds to a bond pad region of the first contact. A second contact is electrically coupled to the active region.

In additional embodiments of the present invention, the second portion corresponds to a region of damage at an interface between the Group III-nitride based layer and the first contact. The region of damage may include a wet or dry etched region of the Group III-nitride based layer, a region of the Group III-nitride based layer and/or first contact exposed to a high energy plasma, a region of the Group III-nitride based layer exposed to a H₂ and/or a region of the Group III-nitride based layer exposed to a high energy laser.

In further embodiments of the present invention, a wire bond pad is provided on the bond pad region of the first contact. Furthermore, the first contact may include a layer of platinum and the layer of platinum may be substantially transparent. Also, the region of damage and the wire bond pad may be self-aligned.

In yet other embodiments of the present invention, light emitting devices and methods of fabricating light emitting devices are provided that include an active region of semiconductor material, a Schottky contact on the active region and a first ohmic contact on the active region and the Schottky contact. A portion of the first ohmic contact on the Schottky contact corresponds to a bond pad region of the first ohmic contact. A second ohmic contact is electrically coupled to the active region. A bond pad may be provided on the bond pad region of the first ohmic contact. The active region may include a Group III-nitride based active region.

In other embodiments of the present invention, light emitting devices and methods of fabricating light emitting devices are provided that include an active region of semiconductor material and a first ohmic contact on the active region. A portion of the first ohmic contact is directly on a region of semiconductor material of a first conductivity type and a second portion of the first ohmic contact is directly on a region of semiconductor material of a second conductivity type opposite the first conductivity type. The second portion corresponds to a bond pad region of the first ohmic contact. A second ohmic contact is electrically coupled to the active region. The region of semiconductor material of the second conductivity type may include a layer of second conductivity type semiconductor material. The region of semiconductor material of the first conductivity type may include a layer of semiconductor material of the first conductivity type and the region of semiconductor material of the second conductivity type may be disposed with the layer of semiconductor material of the first conductivity type. The active region may include a Group III-nitride based active region. A bond pad may also be provided on the bond pad region of the first ohmic contact.

### BRIEF DESCRIPTION OF THE DRAWINGS

FIG. 1 is a cross-sectional view illustrating semiconductor light emitting devices having a current blocking structure according to some embodiments of the present invention.

FIGS. 2A and 2B are cross-sectional views illustrating fabrication of semiconductor devices according to some embodiments of the present invention.

FIGS. 3 and 4 are cross-sectional views of light emitting devices according to further embodiments of the present invention.

### DETAILED DESCRIPTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. As used herein the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers refer to like elements throughout the specification.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated or described as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will also be appreciated by those of skill in the art that references to a structure or feature that is disposed “adjacent” another feature may have portions that overlap or underlie the adjacent feature.

Although various embodiments of LEDs disclosed herein include a substrate, it will be understood by those skilled in the art that the crystalline epitaxial growth substrate on which the epitaxial layers comprising an LED are grown may be removed, and the freestanding epitaxial layers may be mounted on a substitute carrier substrate or submount which may have better thermal, electrical, structural and/or optical characteristics than the original substrate. The invention described herein is not limited to structures having crystalline epitaxial growth substrates and may be utilized in connection with structures in which the epitaxial layers have been removed from their original growth substrates and bonded to substitute carrier substrates.

Some embodiments of the present invention may provide for improved efficacy of a light emitting device by reducing and/or preventing current flow in an active region of the device in a region beneath a wire bond pad or other light absorbing structure. Thus, some embodiments of the present invention may provided light emitting devices and methods of fabricating light emitting devices having a current blocking mechanism below the wire bond pad. By reducing and/or preventing current from being injected directly beneath the wire bond pad, the current may be more likely to be converted to photon emission in areas of the device not under the wire bond pad. Thus, there may be a reduced probability of light being absorbed by the wire bond pad. In some embodiments of the present invention, an increase in efficiency of a light emitting device according to some embodiments of the present invention may be proportional to the size of the wire bond pad.

Embodiments of the present invention may be particularly well suited for use in nitride-based light emitting devices such as Group III-nitride based devices. As used herein, the term “Group III nitride” refers to those semiconducting compounds formed between nitrogen and the elements in Group III of the periodic table, usually aluminum (Al), gallium (Ga), and/or indium (In). The term also refers to ternary and quaternary compounds such as AlGaN and AlInGaN. As is well understood by those in this art, the Group III elements can combine with nitrogen to form binary (e.g., GaN), ternary (e.g., AlGaN, AlInN), and quaternary (e.g., AlInGaN) compounds. These compounds all have empirical formulas in which one mole of nitrogen is combined with a total of one mole of the Group III elements. Accordingly, formulas such as AlₓGa₁₋ₓN where 0≦x≦1 are often used to describe them. However, while embodiments of the present invention are described herein with reference to Group III-nitride based light emitting devices, such as gallium nitride based light emitting devices, certain embodiments of the present invention may be suitable for use in other semiconductor light emitting devices, such as for example, GaAs and/or GaP based devices.

Light emitting devices according to some embodiments of the present invention may include a light emitting diode, laser diode and/or other semiconductor device which includes one or more semiconductor layers, which may include silicon, silicon carbide, gallium nitride and/or other semiconductor materials, a substrate which may include sapphire, silicon, silicon carbide and/or other microelectronic substrates, and one or more contact layers which may include metal and/or other conductive layers. In some embodiments, ultraviolet, blue and/or green LEDs may be provided. The design and fabrication of semiconductor light emitting devices are well known to those having skill in the art and need not be described in detail herein.

For example, light emitting devices according to some embodiments of the present invention may include structures such as the gallium nitride-based LED and/or laser structures fabricated on a silicon carbide substrate such as those devices manufactured and sold by Cree, Inc. of Durham, N.C. The present invention may be suitable for use with LED and/or laser structures that provide active regions such as described in U.S. Pat. Nos. 6,201,262; 6,187,606; 6,120,600; 5,912,477; 5,739,554; 5,631,190; 5,604,135; 5,523,589; 5,416,342; 5,393,993; 5,338,944; 5,210,051; 5,027,168; 5,027,168; 4,966,862 and/or 4,918,497, the disclosures of which are incorporated herein by reference as if set forth fully herein. Other suitable LED and/or laser structures are described in published U.S. Patent Publication No. U.S. 2003/0006418 A1 entitled Group III Nitride Based Light Emitting Diode Structures With a Quantum Well and Superlattice, Group III Nitride Based Quantum Well Structures and Group III Nitride Based Superlattice Structures, published Jan. 9, 2003, as well as published U.S. Patent Publication No. U.S. 2002/0123164 A1 entitled Light Emitting Diodes Including Modifications for Light Extraction and Manufacturing Methods Therefor. Furthermore, phosphor coated LEDs, such as those described in U.S. application Ser. No. 10/659,241, entitled Phosphor-Coated Light Emitting Diodes Including Tapered Sidewalls and Fabrication Methods Therefor, filed Sep. 9, 2003, the disclosure of which is incorporated by reference herein as if set forth fully, may also be suitable for use in embodiments of the present invention. The LEDs and/or lasers may be configured to operate such that light emission occurs through the substrate. In such embodiments, the substrate may be patterned so as to enhance light output of the devices as is described, for example, in the above-cited U.S. Patent Publication No. U.S. 2002/0123164 A1. These structures may be modified as described herein to provide blocking structures according to some embodiments of the present invention.

Thus, for example, embodiments of the present invention may be utilized with light emitting devices having bond pads of differing shapes or sizes. The light emitting devices may be on differing substrates, such as silicon carbide, sapphire, gallium nitride, silicon or other substrate suitable substrate for providing Group III-nitride devices. The light emitting devices may be suitable for subsequent singulation and mounting on a suitable carrier. The light emitting devices may include, for example, single quantum well, multi-quantum well and/or bulk active region devices. Some embodiments of the present invention may be used with devices utilizing a tunneling contact on the p-side of the device.

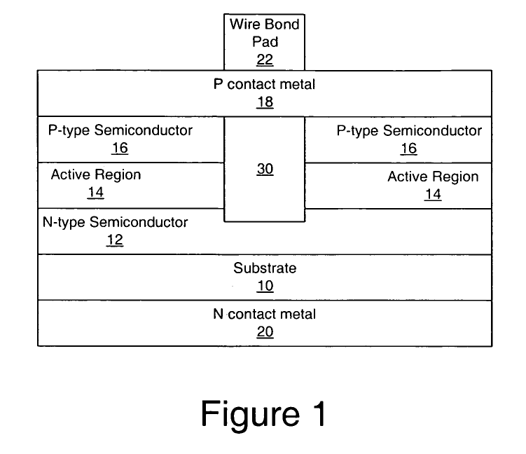

FIG. 1 is a cross-sectional schematic illustration of a light emitting device according to some embodiments of the present invention. As seen in FIG. 1, a substrate 10, such as an n-type silicon carbide substrate, has an optional n-type semiconductor layer 12, such as a gallium nitride based layer, provided thereon. The n-type semiconductor layer 12 may include multiple layers, for example, buffer layers or the like. In some embodiments of the present invention, the n-type semiconductor layer 12 is provided as a silicon doped AlGaN layer, that may be of uniform or gradient composition, and a silicon doped GaN layer.

While described herein with reference to a silicon carbide substrate, in some embodiments of the present invention other substrate materials may be utilized. For example, a sapphire substrate, GaN or other substrate material may be utilized. In such a case, the contact 20 may be located, for example, in a recess that contacts the n-type semiconductor layer 12, so as to provide a second contact for the device. Other configurations may also be utilized.

An active region 14, such as a single or double heterostructure, quantum well, mutli-quantum well or other such active region may be provided on the n-type semiconductor layer. As used herein, the term “active region” refers to a region of semiconductor material of a light emitting device, that may be one or more layers and/or portions thereof, where a substantial portion of the photons emitted by the device when in operation are generated by carrier recombination. In some embodiments of the present invention, the active region refers to a region where substantially all of the photons emitted by the device are generated by carrier recombination.

Also illustrated in FIG. 1 is an optional p-type semiconductor layer 16. The p-type semiconductor material layer 16 may, for example, be a gallium nitride based layer, such as a GaN layer. In particular embodiments of the present invention, the p-type semiconductor layer 16 includes magnesium doped GaN. The p-type semiconductor layer 16 may include one or multiple layers and may be of uniform or gradient composition. In some embodiments of the present invention, the p-type semiconductor layer 16 is part of the active region 14.

A first contact metal layer 18 of contact metal that provides an ohmic contact to the p-type semiconductor material layer 16 is also provided. In some embodiments, the first contact metal layer 18 may function as a current spreading layer. In particular embodiments of the present invention where the p-type semiconductor material layer 16 is GaN, the first contact metal layer 18 may be Pt. In certain embodiments of the present invention, the first contact metal layer 18 is light permeable and in some embodiments is substantially transparent. In some embodiments, the first contact metal layer 18 may be a relatively thin layer of Pt. For example, the first contact metal layer 18 may be a layer of Pt that is about 54 Å thick. A wire bond pad 22 or other light absorbing region is provided on the first contact metal layer 18.

A second contact metal layer 20 of contact metal that provides an ohmic contact to the n-type semiconductor material is also provided. The second contact metal layer 20 may be provided on a side of the substrate 10 opposite the active region 14. As discussed above, in some embodiments of the present invention the second contact metal layer may be provided on a portion of the n-type semiconductor material layer 12, for example, in a recess or at a base of a mesa including the active region. Furthermore, in some embodiments of the present invention, an optional back-side implant or additional epitaxial layers may be provide between the substrate 10 and the second contact metal layer 20.

As is further illustrated in FIG. 1, a reduced conduction region 30 is provided in the active region 14 and is positioned beneath the wire bond pad 22. In some embodiments of the present invention, the reduced conduction region 30 extends through the active region 14. As used herein, reduced conduction refers to a region with reduced current flow over other portions of the active region. In particular embodiments, the reduction is at least an order of magnitude and in some embodiments, substantially all current flow is blocked in the reduced conduction region. In some embodiments of the present invention the reduced conduction region 30 extends through the active region 14. In further embodiments of the present invention, the reduced conduction region 30 extends from the first contact metal layer 18 to the active region 14. In some embodiments, the reduced conduction region extends from the first contact layer 18 into the active region 14. In some embodiments, the reduced conduction region extends from the first contact layer 18 through the active region 14. The reduced conduction region 30 may have substantially the same shape and/or area as the area of the wire bond pad 22 on the first contact metal layer 18. In some embodiments of the present invention, the reduced conduction region 30 has a slightly larger area than the wire bond pad 22 while in other embodiments of the present invention, the reduced conduction region 30 has a slightly smaller area than the wire bond pad 22. In certain embodiments of the present invention, the reduced conduction region 30 does not absorb light or only absorbs a relatively small amount of light. In some embodiments of the present invention, the reduced conduction region 30 is an insulating region.

The reduced conduction region 30 may reduce and/or prevent current flow through the active region 14 in the area beneath the wire bond pad 22 and, therefore, may reduce and/or prevent light generation through carrier recombination in this region. While not being bound by a particular theory of operation, this may be the case because the likelihood that a photon generated in the portion of the active region beneath the wire bond pad 22 is absorbed by the wire bond pad 22 may be higher than if the photon is generated in a portion of the active region that is not beneath the wire bond pad 22. By reducing and/or eliminating the light generated in the active region beneath the wire bond pad 22, the portion of the light generated by the light emitting device that is absorbed by the wire bond pad 22 may be reduced. For a given set of operating conditions, this reduction in the amount of light absorbed by the wire bond pad 22 may result in increased light extraction from the light emitting device as compared to a device operating under the same conditions where light is generated in the region beneath the wire bond pad 22. Thus, some embodiments of the present invention provide a reduced conduction region 30 that extends into and, in some embodiments, through the active region 14 in the area beneath the wire bond pad 22. This may reduce the likelihood that carriers may spread and be injected into the active region 14 beneath the wire bond pad 22 and, thereby, result in photon generation in the area beneath the wire bond pad 22.

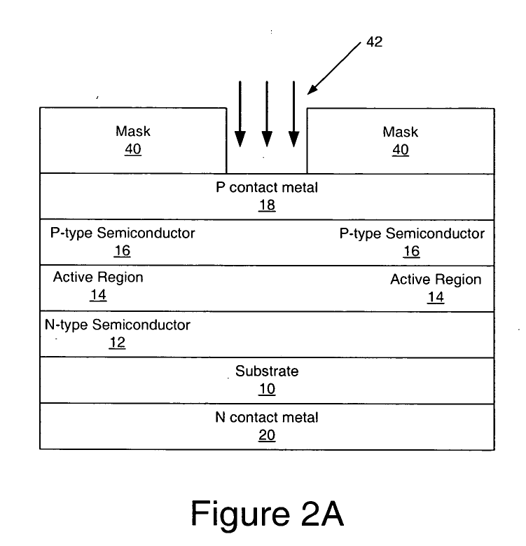

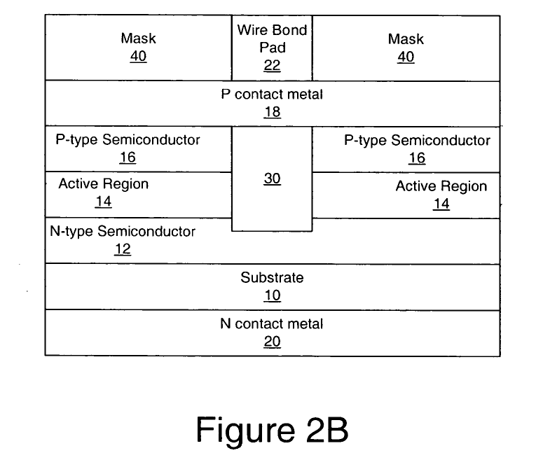

FIGS. 2A and 2B illustrate operations according to some embodiments of the present invention for forming light emitting devices having an reduced conduction region as illustrated in FIG. 1. As seen in FIG. 2A, the various layers/regions of the light emitting device are fabricated. The particular operations in the fabrication of the light emitting device will depend on the structure to be fabricated and are described in the United States patents and/or applications incorporated by reference above and/or are well known to those of skill in the art and, therefore, need not be repeated herein. FIG. 2A also illustrates formation of a mask 40 having a window 42 corresponding to the region where the wire bond pad 22 is to be formed.

An implant is performed using the mask 40 so as to implant atoms into the active region 14 in the region of the wire bond pad 22 so as to form the reduced conduction region 30 as seen in FIG. 2B. Such an implant may, for example, be a nitrogen implant. For example, for a gallium nitride based device, implant conditions of 60 keV, 2×10¹³ cm⁻³ N₂ may produce a non-absorbing and insulating region in Mg doped GaN. The particular implant energy and/or atoms may depend on the structure in which the reduced conduction region 30 is formed.

As seen in FIG. 2B, after implantation, the wire bond pad 22 may be formed in the window 42. Thus, in some embodiments of the present invention, the wire bond pad 22 and the reduced conduction region 30 may be self-aligned. The wire bond pad 22 may be formed, for example, by forming a layer or layers of the metal from which the wire bond pad 22 is formed and then planarizing the layers to provide the wire bond pad 22. The mask 40 may subsequently be removed. Optionally, the mask 40 may be made of an insulating material, such as SiO₂ and/or AlN, and may remain on the device as, for example, a passivation layer, or be removed.

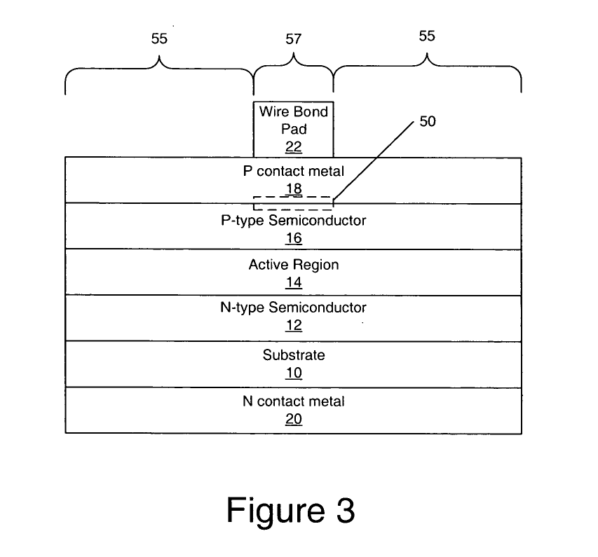

FIG. 3 illustrates light emitting devices according to further embodiments of the present invention. In FIG. 3, the first contact metal layer 18 includes a first portion 55 in contact with the p-type semiconductor material layer 16 that provides an ohmic contact to the p-type semiconductor material layer 16 and a second portion 57 in contact with the p-type semiconductor material layer 16 that does not form an ohmic contact to the p-type semiconductor material layer 16. As used herein the term “ohmic contact” refers to a contact with a specific contact resistivity of less than about 10 e−03 ohm-cm² and, in some embodiments less than about 10 e−04 ohm-cm². Thus, a contact that is rectifying or that has a high specific contact resistivity, for example, a specific contact resistivity of greater than about 10 e−03 ohm-cm², is not an ohmic contact as that term is used herein.

The second portion 57 corresponds to the location of the wire bond pad 22. By not forming an ohmic contact, current injection into the p-type semiconductor material layer 16 in the portion 57 may be reduced and/or prevented. The portion 57 that does not form an ohmic contact may be provided by damaging the p-type semiconductor layer 16 and/or the first contact metal layer 18 in the region 50 beneath the wire bond pad 22.

For example, in gallium nitride based devices, the quality of the interface between the contact metal and the p-type semiconductor material may determine the quality of the resulting ohmic contact. Thus, for example, the p-type semiconductor material layer 16 in the region 50 may be exposed to a high energy plasma, such as Ar, to reduce p-type conductivity before formation of the first contact metal layer 18. Also, the p-type semiconductor material layer 16 and the first contact metal layer 18 in the region 50 may be exposed to a high energy plasma to damage the metal/GaN interface after formation of the first contact metal layer 18. The p-type semiconductor material 16 in the region 50 may be exposed to a H₂ while protecting the other regions of the p-type semiconductor material layer 16 before formation of the first contact metal layer 18. The p-type semiconductor material 16 in the region 50 may be wet or dry etched while protecting the other regions of the p-type semiconductor material layer 16 before formation of the first contact metal layer 18. Also, the p-type semiconductor material layer 16 in the region 50 may be exposed to a high energy laser while protecting the other regions of the p-type semiconductor material 16 before formation of the first contact metal layer 18.

Such selective damaging of the p-type semiconductor material layer 16 and/or metal layer 18 may be provided, for example, using a mask such as described above with reference to FIGS. 2A and 2B and/or by controlling a laser. The particular conditions utilized may vary depending on the procedure utilized and the composition of the p-type semiconductor material layer 16 and/or the first metal contact layer 18.

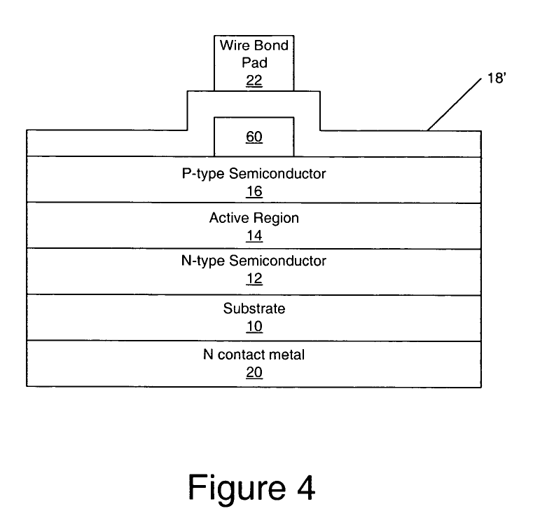

FIG. 4 illustrates light emitting devices according to further embodiments of the present invention. In FIG. 4, a Schottky contact 60 is provided on the p-type semiconductor material layer 16 and the first contact metal layer 18′ formed on the p-type semiconductor material layer 16 and the Schottky contact 60. The wire bond pad 22 is provided on the portion of the first contact metal layer 18′ on the Schottky contact 60. By forming a Schottky contact 60, current injection into the p-type semiconductor material layer 16 from the first contact metal layer 18′ may be reduced and/or prevented in the region of the Schottky contact 60.

Alternatively, a rectifying junction may be provided in the region below the wire bond pad 22. The rectifying junction may be provided, for example, by implanting the p-type semiconductor material layer 16 with n-type ions so as to convert the region beneath the wire bond pad 22 to n-type semiconductor material. Such an implant may, for example, be carried out using a mask such as discussed above with reference to FIGS. 2A and 2B. Alternatively, a region of n-type material could be formed where the Schottky contact 60 is illustrated in FIG. 4 and the first contact metal 18′ could be formed on the region of n-type semiconductor material and the p-type semiconductor material layer 16.

While embodiments of the present invention are illustrated in FIGS. 1 through 4 with reference to particular light emitting device structures, other structures may be provided according to some embodiments of the present invention. Thus, embodiments of the present invention may be provided by any light emitting structure that includes one or more of the various current blocking mechanisms as described above. For example, current blocking mechanisms according to some embodiments of the present invention may be provided in conjunction with the exemplary light emitting device structures discussed in the United States patents and/or applications incorporated by reference above.

Embodiments of the present invention have been described with reference to a wire bond pad 22. As used herein, the term bond pad refers to a light absorbing contact structure. A bond pad may be a single or multiple layers, may be a metal and/or metal alloy and/or may be of uniform of non-uniform composition.

Furthermore, while embodiments of the present invention have been described with reference to a particular sequence of operations, variations from the described sequence may be provided while still benefiting from the teachings of the present invention. Thus, two or more steps may be combined into a single step or steps performed out of the sequence described herein. For example, the reduced conduction region 30 may be formed before or after forming the second contact metal layer 20. Thus, embodiments of the present invention should not be construed as limited to the particular sequence of operations described herein unless stated otherwise herein.

It will be understood by those having skill in the art that various embodiments of the invention have been described individually in connection with FIGS. 1-4. However, combinations and subcombinations of the embodiments of FIGS. 1-4 may be provided according to various embodiments of the present invention.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A light emitting device, comprising:
an active region of semiconductor material;
a first contact on the active region, the first contact having a bond pad region thereon;
a reduced conduction region disposed in the active region beneath the bond pad region of the first contact and configured to reduce current flow through the active region in the region beneath the bond pad region of the first contact; and
a second contact electrically coupled to the active region.

2. The light emitting device of claim 1, wherein the reduced conduction region extends from the first contact to the active region.

3. The light emitting device of claim 1, wherein the reduced conduction region extends from the first contact into the active region.

4. The light emitting device of claim 1, wherein the reduced conduction region extends from the first contact through the active region.

5. The light emitting device of claim 1, wherein the reduced conduction region extends through the active region.

6. The light emitting device of claim 1, further comprising a p-type semiconductor material disposed between the first contact and the active region; and
wherein the reduced conduction region extends from the first contact, through the p-type semiconductor material and through the active region.

7. The light emitting device of claim 1, wherein the active region comprises a Group III-nitride based active region.

8. The light emitting device of claim 1, further comprising a bond pad on the first contact in the bond pad region.

9. The light emitting device of claim 8, wherein the reduced conduction region is self-aligned with the bond pad.

10. The light emitting device of claim 1, wherein the reduced conduction region comprises an insulating region.

11. The light emitting device of claim 10, wherein the reduced conduction region comprises a region that is not light absorbing.

12. The light emitting device of claim 10, wherein the reduced conduction regions comprises an implanted region.

13. A light emitting device, comprising:
a Group III-nitride based active region;
a first contact directly on a Group III-nitride based layer on the active region, the first contact having a first portion that makes ohmic contact to the Group III-nitride based layer and a second portion that does not make ohmic contact to the Group III-nitride based layer, the second portion corresponding to a bond pad region of the first contact; and
a second contact electrically coupled to the active region.

14. The light emitting device of claim 13, wherein the second portion corresponds to a region of damage at an interface between the Group III-nitride based layer and the first contact.

15. The light emitting device of claim 14, wherein the region of damage comprises a wet or dry etched region of the Group III-nitride based layer.

16. The light emitting device of claim 14, wherein the region of damage comprises a region of the Group III-nitride based layer and/or first contact exposed to a high energy plasma.

17. The light emitting device of claim 14, wherein the region of damage comprises a region of the Group III-nitride based layer exposed to a H₂.

18. The light emitting device of claim 14, wherein the region of damage comprises a region of the Group III-nitride based layer exposed to a high energy laser.

19. The light emitting device of claim 13, further comprising a wire bond pad on the bond pad region of the first contact.

20. The light emitting device of claim 13, wherein the first contact comprises a layer of platinum.

21. The light emitting device of claim 20, wherein the layer of platinum is substantially transparent.

22. The light emitting device of claim 14, further comprising a wire bond pad on the bond pad region of the first contact, and wherein the region of damage and the wire bond pad are self-aligned.

23. A light emitting device, comprising:
an active region of semiconductor material;
a Schottky contact on the active region;
a first ohmic contact on the active region and the Schottky contact, a portion of the first ohmic contact on the Schottky contact corresponding to a bond pad region of the first ohmic contact; and
a second ohmic contact electrically coupled to the active region.

24. The light emitting device of claim 23, further comprising a bond pad on the bond pad region of the first ohmic contact.

25. The light emitting device of claim 23, wherein the active region comprises a Group III-nitride based active region.

26. A light emitting device, comprising:
an active region of semiconductor material;
a first ohmic contact on the active region, a portion of the first ohmic contact directly on a region of semiconductor material of a first conductivity type and a second portion of the first ohmic contact directly on a region of semiconductor material of a second conductivity type opposite the first conductivity type, the second portion corresponding to a bond pad region of the first ohmic contact; and
a second ohmic contact electrically coupled to the active region.

27. The light emitting device of claim 26, wherein the region of semiconductor material of the second conductivity type comprises a layer of second conductivity type semiconductor material.

28. The light emitting device of claim 26, wherein region of semiconductor material of the first conductivity type comprises a layer of semiconductor material of the first conductivity type and wherein the region of semiconductor material of the second conductivity type is disposed with the layer of semiconductor material of the first conductivity type.

29. The light emitting device of claim 26, wherein the active region comprises a Group III-nitride based active region.

30. The light emitting device of claim 26, further comprising a bond pad on the bond pad region of the first ohmic contact.

31. A method of fabricating a light emitting device, comprising:
forming an active region of semiconductor material;
forming a first contact on the active region, the first contact having a bond pad region thereon;
forming a reduced conduction region disposed in the active region beneath the bond pad region of the first contact and configured to block current flow through the active region in the region beneath the bond pad region of the first contact; and
forming a second contact electrically coupled to the active region.

32. The method of claim 31, wherein the reduced conduction region extends from the first contact to the active region.

33. The method of claim 31, wherein the reduced conduction region extends from the first contact into the active region.

34. The method of claim 31, wherein the reduced conduction region extends from the first contact through the active region.

35. The method of claim 31, wherein the reduced conduction region extends through the active region.

36. The method of claim 31, further comprising forming a p-type semiconductor material disposed between the first contact and the active region; and
wherein the reduced conduction region extends from the first contact, through the p-type semiconductor material and through the active region.

37. The method of claim 31, wherein the active region comprises a Group III-nitride based active region.

38. The method of claim 31, further comprising forming a bond pad on the first contact in the bond pad region.

39. The method of claim 38, wherein the reduced conduction region is self-aligned with the bond pad.

40. The method of claim 31, wherein forming a reduced conduction region comprises:
forming a mask layer on the first ohmic contact, the mask layer having an opening corresponding to the bond pad region; and
implanting atoms in the active region through the opening in the mask layer.

41. The method of claim 40, further comprising forming a bond pad in the opening in the mask layer.

42. A method of fabricating a light emitting device, comprising:
forming a Group III-nitride based active region;
forming a first contact directly on a Group III-nitride based layer on the active region, the first contact having a first portion that makes ohmic contact to the Group III-nitride based layer and a second portion that does not make ohmic contact to the Group III-nitride based layer, the second portion corresponding to a bond pad region of the first contact; and
forming a second contact electrically coupled to the active region.

43. The method of claim 42, wherein forming a first contact comprises damaging a region of the Group III-nitride based layer corresponding to the second portion of the first contact.

44. The method of claim 43, wherein damaging a region comprises wet or dry etching the region of the Group III-nitride based layer.

45. The method of claim 43, wherein damaging a region comprises exposing the region of the Group III-nitride based layer and/or first contact to high energy plasma.

46. The method of claim 43, wherein damaging a region comprises exposing the region of the Group III-nitride based layer to H₂.

47. The method of claim 43, wherein damaging a region comprises exposing the region of the Group III-nitride based layer to a high energy laser.

48. The method of claim 42, further comprising forming a wire bond pad on the bond pad region of the first contact.

49. A method of fabricating a light emitting device, comprising:
forming an active region of semiconductor material;
forming a Schottky contact on the active region;
forming a first ohmic contact on the active region and the Schottky contact, a portion of the first ohmic contact on the Schottky contact corresponding to a bond pad region of the first ohmic contact; and
forming a second ohmic contact electrically coupled to the active region.

50. The method of claim 49, further comprising forming a bond pad on the bond pad region of the first ohmic contact.

51. The method of claim 49, wherein the active region comprises a Group III-nitride based active region.

52. A method of fabricating a light emitting device, comprising:
forming an active region of semiconductor material;
forming a first ohmic contact on the active region, a portion of the first ohmic contact is directly on a region of semiconductor material of a first conductivity type and a second portion of the first ohmic contact is directly on a region of semiconductor material of a second conductivity type opposite the first conductivity type, the second portion corresponding to a bond pad region of the first ohmic contact; and
forming a second ohmic contact electrically coupled to the active region.

53. The method of claim 52, wherein the region of semiconductor material of the second conductivity type comprises a layer of second conductivity type semiconductor material.

54. The method of claim 52, wherein region of semiconductor material of the first conductivity type comprises a layer of semiconductor material of the first conductivity type and wherein the region of semiconductor material of the second conductivity type is disposed with the layer of semiconductor material of the first conductivity type.

55. The method of claim 52, wherein the active region comprises a Group III-nitride based active region.

56. The method of claim 52, further comprising forming a bond pad on the bond pad region of the first ohmic contact.
